(19) United States
(12) Patent Application Publication
(10) Pub. No.: US 2022/0165927 A1
(43) Pub. Date: May 26, 2022

(54) SEMICONDUCTOR LIGHT-EMITTING DEVICE AND METHOD OF MANUFACTURING SAME

(71) Applicant: STANLEY ELECTRIC CO., LTD., Tokyo (JP)

(72) Inventor: Kenji Ikeda, Tokyo (JP)

(73) Assignee: STANLEY ELECTRIC CO., LTD., Tokyo (JP)

(21) Appl. No.: 17/527,247

(22) Filed: Nov. 16, 2021

(30) Foreign Application Priority Data
Nov. 24, 2020 (JP) 2020-194031

(51) Int. Cl. H01L 33/62; H01L 33/00

(52) U.S. Cl. CPC H01L 33/62; H01L 2933/0066; H01L 33/005

(57) ABSTRACT

A light-emitting device includes: a semiconductor light-emitting element; a substrate having a mount portion for the light-emitting element and a frame portion that is provided to stand on an outer peripheral part of the mount portion and has, on a top surface thereof, a substrate joint surface to which an annular substrate metal layer is fixed; and a light-transmitting cap made of glass and having a window portion that allows light emitted from the light-emitting element to pass through and a cap joint surface to which an annular cap metal layer of a size corresponding to the substrate metal layer is fixed, the cap joint surface being joined to the substrate metal layer by a joint layer to seal the light-transmitting cap to the substrate, wherein the top surface of the frame portion is inclined to decrease in height from an outer peripheral part toward an inner peripheral part of the frame portion.

### BACKGROUND OF THE INVENTION

### 1. Field of the Invention

The present invention relates to a semiconductor light-emitting device and a method of manufacturing the same, and particularly to a semiconductor light-emitting device having enclosed therein a semiconductor light-emitting element that emits ultraviolet light and a method of manufacturing the same.

### 2. Description of the Related Art

Semiconductor devices in which semiconductor elements are enclosed in semiconductor packages are conventionally known. In the case of a semiconductor light-emitting module, a support on which a semiconductor light-emitting element is placed and a transparent window member such as glass that allows light from the light-emitting element to pass through are joined and sealed airtight.

For example, Patent Literatures 1 and 2 each disclose a semiconductor light-emitting module in which a substrate having a recess storing a semiconductor light-emitting element and a window member are joined.

Patent Literature 3 discloses an ultraviolet light-emitting device in which a mount substrate having an ultraviolet light-emitting element mounted thereon, a spacer, and a cover made of glass are joined.

Patent Literature 4 discloses an optical semiconductor device in which light output at a side surface of an optical semiconductor element is reflected by a metal layer provided on an inclined light-reflecting surface to be directed to a window member to thus enhance light output.

### CITATION LIST

### Patent Literatures

Patent Literature 1: Japanese Patent Application Laid-Open No. 2015-18873
Patent Literature 2: Japanese Patent Application Laid-Open No. 2018-93137
Patent Literature 3: Japanese Patent Application Laid-Open No. 2016-127255
Patent Literature 4: Japanese Patent Application Laid-Open No. 2018-037583

### SUMMARY OF THE INVENTION

However, further improvement in sealability and joint reliability between a substrate and a window member is needed. A semiconductor light-emitting element that emits ultraviolet light, in particular an AlGaN-based semiconductor light-emitting element, tends to degrade if airtightness is insufficient. Hence, a semiconductor device including the semiconductor light-emitting element is required to be highly airtight.

Moreover, AlGaN-based crystals degrade due to moisture. In particular, when the emission wavelength is shorter, AlGaN-based crystals are more likely to degrade as Al increases in composition. In view of this, a structure in which a substrate and a glass cover are made airtight by a metal joint material is used as an airtight structure that keeps moisture from entering a package containing a light-emitting element. This structure, however, has the problem in that airtightness is insufficient in the case of being used in a humid environment or a wet area.

For example, a ceramic substrate and a window member are provided with respective metal layers, and a joint material such as an AuSn sheet is sandwiched between these metal layers and melted to form an airtight structure. The inventor of the present invention, however, learned that a time difference in melting between the parts of the AuSn sheet in contact with the metal layers and the parts of the AuSn sheet not in contact with the metal layers causes poor airtightness.

More specifically, metalized Au is dissolved in the parts that have melted first, and the resultant Au ratio increases the melting point and the parts solidify. Hence, the parts other than the parts that have melted and solidified first undergo subsequent melting. Such inconsistency in melting start point can cause poor joint and poor airtightness. Further, strain (residual strain) caused by melting and solidification remains in a joint layer, which may induce cracks or the like during use and cause poor airtightness.

In view of the above, the present invention has an object of providing a semiconductor device having high reliability, i.e. maintaining high airtightness even in long-term use, and having high environmental resistance such as moisture resistance and corrosion resistance, and a method of manufacturing the same. The present invention also has an object of providing a semiconductor device including a highly reliable airtight joint that can prevent degradation inside a joint layer without residual stress which causes cracks in the joint portion, and a method of manufacturing the same.

A semiconductor light-emitting device according to an embodiment of the present invention includes: a semiconductor light-emitting element; a substrate having a mount portion for the semiconductor light-emitting element and a frame portion that is provided to stand on an outer peripheral part of the mount portion and has, on a top surface thereof, a substrate joint surface to which an annular substrate metal layer is fixed; and a light-transmitting cap made of glass and having a window portion that allows light emitted from the semiconductor light-emitting element to pass through and a cap joint surface to which an annular cap metal layer of a size corresponding to the substrate metal layer is fixed, the cap joint surface being joined to the substrate metal layer by a joint layer to seal the light-transmitting cap to the substrate with an internal space that houses or contains the semiconductor light-emitting element therein, wherein the top surface of the frame portion is inclined to decrease in height from an outer peripheral part toward an inner peripheral part of the frame portion.

### BRIEF DESCRIPTION OF THE DRAWINGS

FIG. 1A is a top view schematically illustrating a semiconductor light-emitting device 10 according to Embodiment 1.

FIG. 1B is a side view schematically illustrating the semiconductor light-emitting device 10.

FIG. 1C is a bottom view schematically illustrating the semiconductor light-emitting device 10.

FIG. 1D is a view schematically illustrating the internal structure of the semiconductor light-emitting device 10.

FIG. 2A is a sectional view schematically illustrating the semiconductor light-emitting device 10 along line A-A in FIG. 1A.

FIG. 2B is a partially enlarged sectional view of a joint portion (W part) in FIG. 2A.

FIG. 2C is a partially enlarged sectional view of the joint portion after the joint material melts.

FIG. 3A is a top view schematically illustrating a light-transmitting cap 13 in a semiconductor light-emitting device 50 according to Embodiment 2.

FIG. 3B is a view schematically illustrating a method of forming AuSn bumps 22B.

FIG. 4A is a partially enlarged sectional view of a joint portion between the light-transmitting cap 13 and a frame 11A of a substrate 11.

FIG. 4B is a top view schematically illustrating a state in which AuSn bumps 22B coalesce as a result of melting.

FIG. 5A is a partially enlarged sectional view of a joint portion between the light-transmitting cap 13 and the frame 11A of the substrate 11 in a semiconductor light-emitting device 60 according to Embodiment 3.

FIG. 5B is a top view schematically illustrating a state in which AuSn bumps 22B coalesce (upper drawing) and a side view schematically illustrating an extension portion 12E of a substrate metal layer 12 (lower drawing).

FIG. 6A is a partially enlarged sectional view of a joint portion between the light-transmitting cap 13 and the frame 11A of the substrate 11 in a semiconductor light-emitting device 70 according to Embodiment 4.

FIG. 6B is a side view schematically illustrating the extension portion 12E of the substrate metal layer 12 on the inner wall of the frame 11A.

FIG. 7A is a sectional view schematically illustrating a method of manufacturing the substrate 11 in Embodiments 1 and 2.

FIG. 7B is a sectional view schematically illustrating the method of manufacturing the substrate 11 in Embodiments 1 and 2.

FIG. 8 is a sectional view schematically illustrating a method of manufacturing the substrate 11 in Embodiment 3.

FIG. 9 is a sectional view schematically illustrating a method of manufacturing the substrate 11 in Embodiment 4.

### DESCRIPTION OF THE PREFERRED EMBODIMENTS

Preferred embodiments of the present invention will be described below. These embodiments may be modified or combined as appropriate. In the following description and the attached drawings, substantially same or equivalent parts are given the same reference signs.

### Embodiment 1

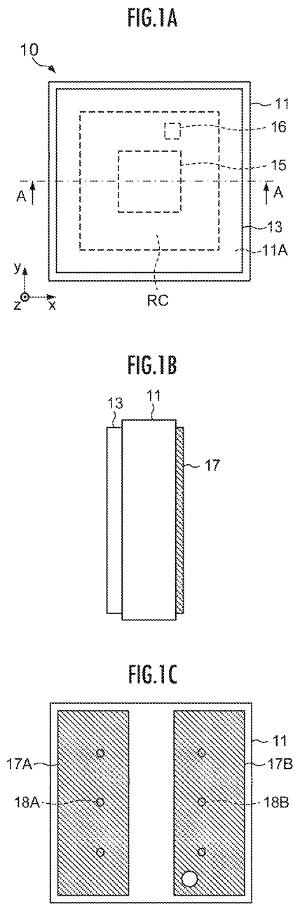

FIG. 1A is a top view schematically illustrating a semiconductor light-emitting device 10 according to Embodiment 1 of the present invention. FIG. 1B is a side view schematically illustrating the semiconductor light-emitting device 10. FIG. 1C is a bottom view schematically illustrating the semiconductor light-emitting device 10. FIG. 1D is a view schematically illustrating the internal structure of the semiconductor light-emitting device 10.

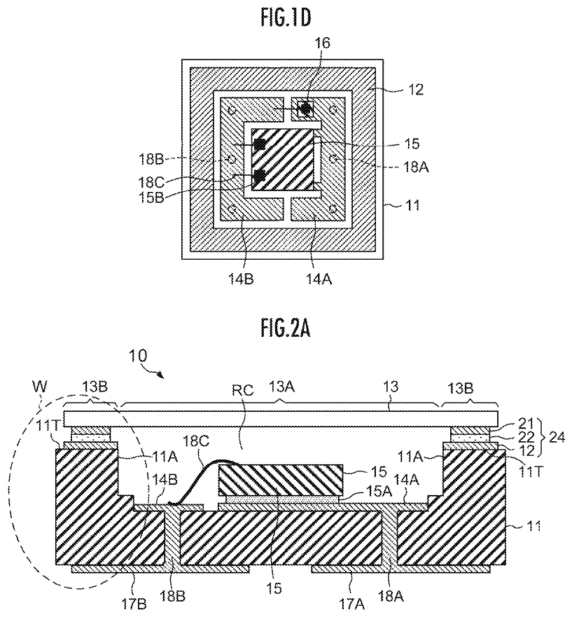

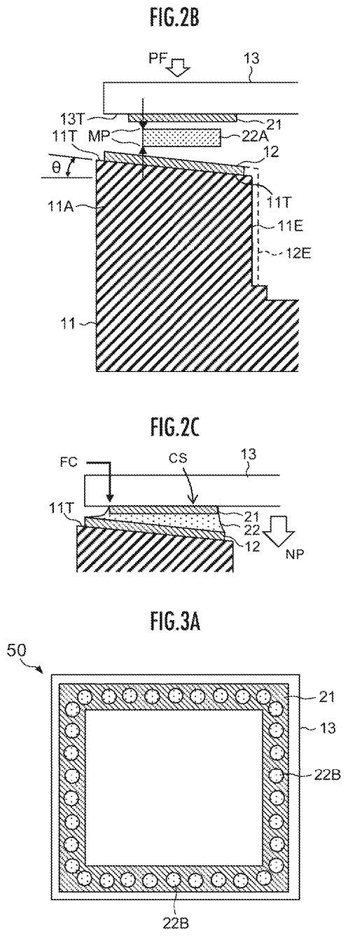

FIG. 2A is a sectional view schematically illustrating the semiconductor light-emitting device 10 along line A-A in FIG. 1A. FIG. 2B is a partially enlarged sectional view of a joint portion (W part) in FIG. 2A. FIG. 2C is a partially enlarged sectional view of the joint portion after the joint material melts.

As illustrated in FIGS. 1A and 2A, a substrate 11 in the semiconductor light-emitting device 10 has a recess RC which is a space storing a semiconductor light-emitting element 15. In more detail, the substrate 11 is formed as a housing structure (frame body structure) having a prismatic recess RC defined by a frame 11A which is a frame portion provided to stand on the outer peripheral part of the substrate 11. The frame 11A has a rectangular frame shape (i.e. a hollow quadrangular prism shape).

In the drawings, the side surfaces of the substrate 11 are parallel to x direction and y direction, and the upper surface of the substrate 11 is parallel to xy plane.

As illustrated in FIGS. 1A to 1D, the semiconductor light-emitting device 10 is formed by joining the substrate 11 having the frame 11A of a rectangular frame shape and a light-transmitting cap 13 which is a light-transmitting window made of rectangular plate glass. In more detail, a metal layer 12 (hereafter also referred to as “substrate metal layer 12”) of a rectangular annular shape is formed on the top surface 11T of the frame 11A of the substrate 11 and joined to the light-transmitting cap 13, as illustrated in FIG. 1D.

As illustrated in FIG. 2A, the light-transmitting cap 13 has a window portion 13A and a cap outer edge portion (hereafter also simply referred to as “outer edge portion”) 13B. In more detail, the cap outer edge portion 13B is the outer edge portion of the rectangular annular light-transmitting cap 13, and the window portion 13A which is a light-transmitting portion is located on the inside. A rectangular annular cap metal layer 21 is fixed to the bottom surface of the cap outer edge portion 13B, thus forming a joint surface (hereafter also referred to as “cap joint surface”). The window portion 13A of the light-transmitting cap 13 may have a convex shape, a concave shape, a convex lens shape, or a concave lens shape.

The cap metal layer 21 is joined to the substrate metal layer 12 by a joint layer 22, as illustrated in FIG. 2A. Thus, a joint portion 24 is formed, and the airtightness between the substrate 11 and the light-transmitting cap 13 is maintained. That is, the cap metal layer 21 has a shape and a size corresponding to the substrate metal layer 12, and is joined to the substrate metal layer 12 by the joint layer 22.

As illustrated in FIGS. 1D and 2A, a first wiring electrode (for example, anode electrode) 14A and a second wiring electrode (for example, cathode electrode) 14B which are wiring electrodes in the semiconductor light-emitting device 10 are provided on the substrate 11 (the first wiring electrode 14A and the second wiring electrode 14B are hereafter referred to as “wiring electrodes 14” when not distinguished from each other).

The semiconductor light-emitting element 15 such as a light-emitting diode (LED) or a semiconductor laser is joined onto the first wiring electrode 14A by a metal joint layer 15A, and a bonding pad 15B of the light-emitting element 15 is electrically connected to the second wiring electrode 14B through a bonding wire 18C.

### (Light-Emitting Element, Substrate, Electrode, Protection Element)

The light-emitting element 15 is an aluminum gallium nitride (AlGaN)-based semiconductor light-emitting element (LED) in which a semiconductor structure layer including an n-type semiconductor layer, a light-emitting layer, and a p-type semiconductor layer is formed. In the light-emitting element 15, the semiconductor structure layer is formed on (i.e. joined to) a conductive support substrate (silicon: Si) through a reflection layer.

The light-emitting element 15 includes an anode electrode (not illustrated) on the opposite surface (also referred to as the back surface of the light-emitting element 15) to the surface of the support substrate to which the semiconductor structure layer is joined, and is electrically connected to the first wiring electrode 14A on the substrate 11. The light-emitting element 15 also includes a cathode electrode (pad 15B) on the opposite surface (also referred to as the front surface of the light-emitting element 15) to the surface of the semiconductor structure layer to which the support substrate is joined, and is electrically connected to the second wiring electrode 14B through a bonding wire.

The light-emitting element 15 is not limited to the foregoing type in which the semiconductor structure layer is joined to the support substrate, and may be of a type in which the semiconductor structure layer is formed on a growth substrate that transmits light emitted from the semiconductor structure layer.

For example, in the case where the growth substrate is conductive, the light-emitting element 15 includes the cathode electrode on the back surface of the growth substrate (i.e. the opposite surface to the semiconductor structure layer) (not illustrated), and the anode electrode (pad electrode for bonding wire connection) on the upper surface of the semiconductor structure layer. The cathode electrode of the light-emitting element is joined onto the first wiring electrode 14A through the metal joint layer 15A, and the pad electrode of the light-emitting element is electrically connected to the second wiring electrode 14B through the bonding wire 18C.

In the case where the growth substrate is insulating, the light-emitting element 15 includes the anode electrode on the p-type semiconductor layer on the upper side of the semiconductor structure layer, and the cathode electrode on the n-type semiconductor layer. The anode electrode and the cathode electrode of the light-emitting element are respectively joined to the first wiring electrode 14A and the second wiring electrode 14B through a metal joint layer.

The light-emitting element 15 is preferably an aluminum nitride-based light-emitting element that emits ultraviolet light of 265 nm to 415 nm in wavelength. Specifically, a light-emitting element having a light emission center wavelength of 265 nm, 275 nm, 355 nm, 365 nm, 385 nm, 405 nm, or 415 nm is used.

Semiconductor crystals forming aluminum nitride-based light-emitting elements that emit ultraviolet light (UV-LED elements) have high Al composition, and are susceptible to oxidative degradation by oxygen (O₂) or water (H₂O). In the case where a joint member containing organic matter such as flux is used to join the light-emitting element 15 to the first wiring electrode 14A, residual flux (organic matter) causes accumulation of carbide on the front surface of the light-emitting element. Such accumulation of carbide can be prevented by mixing filler gas with a small amount of O₂. Mixed O₂ poses no problem as it is inactivated before degrading the light-emitting element 15.

A protection element 16 that is a Zener diode (ZD) connected to the first wiring electrode 14A and the second wiring electrode 14B is provided on the substrate 11, and prevents the light-emitting element 15 from electrostatic discharge damage.

As illustrated in FIG. 1C, a first mount electrode 17A and a second mount electrode 17B (hereafter referred to as “mount electrodes 17” when not distinguished from each other) respectively connected to the first wiring electrode 14A and the second wiring electrode 14B are provided on the back surface of the substrate 11. Specifically, the first wiring electrode 14A and the second wiring electrode 14B are respectively connected to the first mount electrode 17A and the second mount electrode 17B through metal vias 18A and 18B (hereafter referred to as “metal vias 18” when not distinguished from each other).

The wiring electrodes 14, the mount electrodes 17, and the metal vias 18 are, for example, tungsten/nickel/gold (W/Ni/Au) or nickel chromium/gold/nickel/gold (NiCr/Au/Ni/Au).

With reference to FIG. 2A, the semiconductor light-emitting device 10 is configured to be mounted on a wiring circuit substrate (not illustrated). Voltage application to the first mount electrode 17A and the second mount electrode 17B causes the light-emitting element 15 to emit light, and emitted light LE from the front surface (light extraction surface) of the light-emitting element 15 is radiated to the outside through the light-transmitting cap 13.

The joint between the substrate 11 and the cap outer edge portion 13B of the light-transmitting cap 13 will be described below.

### (Joint Between Light-Transmitting Cap 13 and Cap Outer Edge Portion 13B)

As illustrated in FIGS. 2A and 2B, the substrate 11 has the frame 11A (frame portion) provided to stand on the outer peripheral part of the substrate 11. The top surface 11T which is the upper end surface of the frame 11A has an annular shape (rectangular annular shape in this embodiment), and is formed as an inclined surface that is inclined downward (i.e. away from the light-transmitting cap 13) at an inclination angle θ from the outer peripheral part toward the inner peripheral part of the frame 11A (i.e. toward the recess RC). That is, the top surface 11T of the frame 11A is inclined at the inclination angle θ so as to decrease in height from the outer peripheral part toward the inner peripheral part.

FIG. 2B is a view for explaining joint stability when joining the light-transmitting cap 13 and the frame 11A of the substrate 11. The substrate metal layer 12 fixed to the top surface II T which is the inclined surface of the frame 11A and the cap metal layer 21 fixed to the cap joint surface 13T of the cap outer edge portion 13B (cap joint portion) are joined by a joint material 22A to form the joint layer 22 (FIG. 2C).

In this embodiment, a circular annular AuSn ribbon not containing flux is used as the joint material 22A. When the joint material (AuSn ribbon) 22A is pressed (joining pressure PF) between the substrate metal layer 12 at the upper end of the frame and the cap metal layer 21, the outer edges of the ribbon are pressed from both sides, i.e. from the substrate metal layer 12 and the cap metal layer 21, and come into close contact with the substrate metal layer 12 and the cap metal layer 21.

Heating (for example, 280° C.) causes the close contact part on the outer side of the ribbon to reach a melting start point MP, and the joint material 22A melts and solidifies inward from this part to join the substrate metal layer 12 and the cap metal layer 21. Since the melting and solidification progress inward from the melting start point MP the joint layer 22 is kept from containing residual stress. This produces a highly reliable joint without residual stress which causes cracks in the joint portion.

The joint layer volume (Vc) is determined based on the shape of the top surface 11T of the frame 11A inclined at the inclination angle θ with respect to the cap joint surface 13T. Hence, by setting the joint material volume (Vs) of the AuSn joint material to be equivalent to the joint layer volume (Vc) (i.e. Vs≈Vc), the joint layer 22 can be formed while keeping the AuSn joint material from protruding.

In the case where the internal pressure of the semiconductor light-emitting device 10 is set to reduced pressure in a range of room temperature to rated operating temperature (80° C.), the window member (glass) is stressed inward in the device, as illustrated in FIG. 2C. This stress (negative pressure stress NP) acts in the compressive direction for the joint layer 22 with the outer end of the joint as a fulcrum FC (compressive stress CS), so that cracks are suppressed.

The substrate metal layer 12 can extend to the inner wall 11E (indicated by the dashed line in the drawing) of the frame 11A. This prevents water and flux residues from adsorbing on the front surface of the ceramic substrate 11.

As described above, with the semiconductor light-emitting device 10 according to this embodiment, the melting start point of the joint material is set, so that the joint stability can be improved. Moreover, since the volume of the joint layer 22 can be set and adjusted, leakage and dripping of the joint material can be prevented.

### Embodiment 2

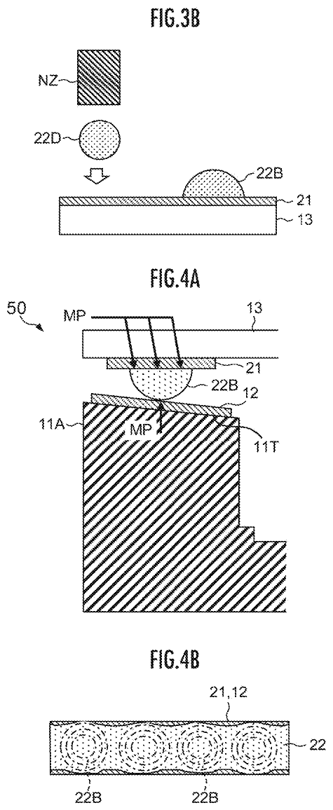

FIG. 3A is a top view schematically illustrating a light-transmitting cap 13 in a semiconductor light-emitting device 50 according to Embodiment 2. The light-transmitting cap 13 before being joined to the substrate 11 is illustrated in the drawing.

AuSn bumps 22B (joint material bumps) as a joint material not containing flux are arranged on the cap metal layer 21 of the light-transmitting cap 13. The plurality of AuSn bumps 22B are formed on the whole circumference of the rectangular annular cap metal layer 21, and are arranged at such intervals that allow adjacent bumps to coalesce upon melting when joining the light-transmitting cap 13 to the substrate 11.

FIG. 3B is a view schematically illustrating a method of forming the AuSn bumps 22B. Specifically, an AuSn melt 22D is made to strike the cap metal layer 21 from a nozzle NZ to form the AuSn bumps 22B.

Since each AuSn bump 22B is formed by deposition of the melt AuSn on the cap metal layer 21, the thermal resistance of the interface between the surface of the cap metal layer 21 and the AuSn bump 22B is low. The AuSn bump 22B may be formed on the substrate metal layer 12 of the frame 11A of the substrate 11.

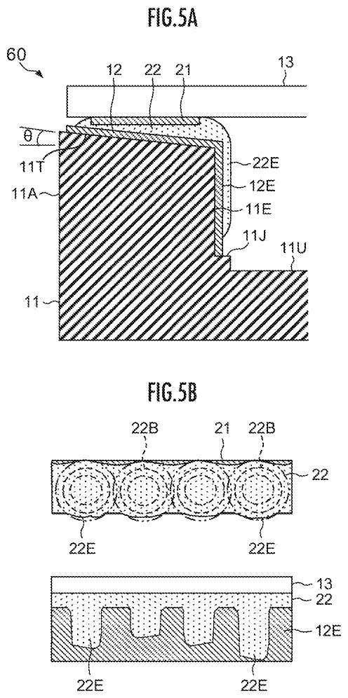

FIG. 4A is a partially enlarged sectional view of the joint portion between the light-transmitting cap 13 and the frame 11A (frame portion) of the substrate 11. The top surface 11T which is the upper end surface of the frame 11A is formed as an inclined surface that is inclined at the inclination angle θ toward the inside of the recess RC, as in the foregoing Embodiment 1.

The AuSn bumps 22B are deposited on the cap metal layer 21 and have good heat conduction, so that all of the AuSn bumps 22B melt simultaneously as a result of heating. Moreover, since each AuSn bump 22B is in point contact with the substrate metal layer 12, the contact is low in thermal resistance even with weak pressing, and thus serves as a stable heat-melting point MP.

FIG. 4B is a top view schematically illustrating a state in which AuSn bumps 22B coalesce as a result of melting. Adjacent bumps coalesce as a result of melting, and the joint layer 22 is formed between the substrate metal layer 12 and the cap metal layer 21.

By setting the joint material volume (Vs) of the AuSn bumps 22B to be equivalent to the joint layer volume (Vc) (i.e. Vs≈Vc), the joint layer 22 can be formed while keeping the AuSn joint material from protruding out of the substrate metal layer 12 or the cap metal layer 21 (FIGS. 4B and 2C).

Thus, even when the joint material is formed in dots (AuSn bumps), all bumps simultaneously melt and spread on the substrate metal layer 12 and the cap metal layer 21 and coalesce in the process, as a result of which an airtight joint of high reliability can be obtained.

The semiconductor light-emitting device according to this embodiment also has the same advantages as the semiconductor light-emitting device according to Embodiment 1. In detail, the melting start point of the joint material is set, so that the joint stability can be improved. Moreover, since the volume of the joint layer 22 can be set and adjusted, protrusion of the joint material can be prevented.

### Embodiment 31

FIG. 5A is a partially enlarged sectional view of a joint portion between the light-transmitting cap 13 and the frame 11A of the substrate 11 in a semiconductor light-emitting device 60 according to Embodiment 3. The top surface 11T which is the upper end surface of the frame 11A is formed as an inclined surface that is inclined at the inclination angle θ from the outer peripheral part toward the inner peripheral part of the frame 11A to thus decrease in height, as in the foregoing Embodiments 1 and 2.

In this embodiment, the substrate metal layer 12 extends from the top surface 11T to the inner wall (inner surface) 11E of the frame 11A so as to cover at least part of the inner wall 11E of the frame 11A.

The joint layer 22 extends to reach and lie on this extension portion (metal layer extension portion) 12E of the substrate metal layer 12. For the extension portion (joint layer extension portion) 22E of the joint layer 22, the joint material volume (Vs) of the AuSn bumps 22B described in Embodiment 2 is set to the joint layer volume (Vc)+the drip amount (α) so that AuSn will drip onto the extension portion 12E of the substrate metal layer 12 upon melting.

FIG. 5B is a top view schematically illustrating a state in which the AuSn bumps 22B melt and coalesce (upper drawing), and a side view schematically illustrating the extension portion 12E of the substrate metal layer 12 on the inner wall 11E of the frame 11A (lower drawing).

As illustrated in the top view (upper drawing), as a result of the AuSn bumps 22B melting, the bumps coalesce and the melted joint material (AuSn) drips onto the inner wall 11E of the frame 11A due to the inclination of the top surface 11T of the frame 11A, forming an extension portion 22E of the joint layer 22.

With the semiconductor light-emitting device 60 according to this embodiment, the joint material (AuSn) dripping onto the inner wall 11E of the frame 11A adsorbs and fixes active gas (water, flux component gas) remaining in the internal space of the semiconductor light-emitting device 60 (the space of the recess RC. This prevents degradation caused by ultraviolet light and active gas inside the joint portion, i.e. the joint layer 22, between the substrate metal layer 12 and the cap metal layer 21, so that an airtight joint of high reliability can be obtained.

The semiconductor light-emitting device according to this embodiment also has the same advantages as the semiconductor light-emitting devices according to the foregoing embodiments. In detail, the melting start point of the joint material is set, so that the joint stability can be improved. Moreover, since the volume of the joint layer 22 can be set and adjusted, leakage of the joint material can be prevented.

### Embodiment 4

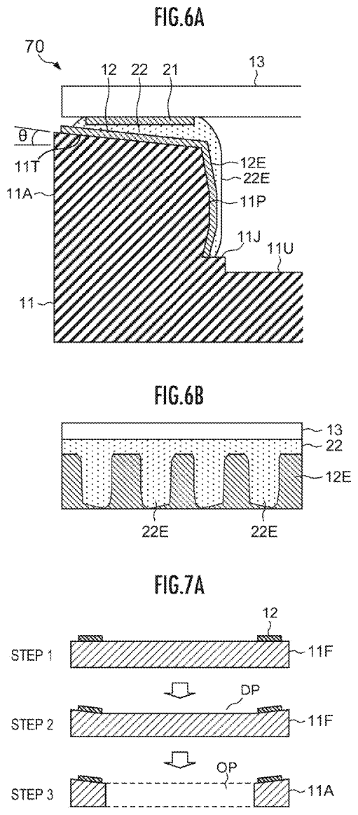

FIG. 6A is a partially enlarged sectional view of a joint portion between the light-transmitting cap 13 and the frame 11A of the substrate 11 in a semiconductor light-emitting device 70 according to Embodiment 4. The top surface 11T which is the upper end surface of the frame 11A is formed as an inclined surface that is inclined at the inclination angle θ so as to decrease in height from the outer peripheral part toward the inner peripheral part of the frame 11A, as in the foregoing Embodiments 1 to 3. FIG. 6B is a side view schematically illustrating the extension portion 12E of the substrate metal layer 12 on the inner wall of the frame 11A.

The semiconductor light-emitting device 70 according to this embodiment differs from the semiconductor light-emitting device 60 according to Embodiment 3 in that the inner wall of the frame 11A is formed as a projecting surface 11P projecting to the internal space (the space of the recess RC). At the lower end of the projecting surface 11P, a step portion 11J is formed as a step with respect to an element mount surface (and electrode placement surface) 11U of the substrate 11 and projects more to the internal space than the projecting surface 11P.

As illustrated in FIGS. 6A and 6B, as a result of the extension portion 12E of the substrate metal layer 12 extending to reach the step portion 11J, the AuSn joint material which drips down can be easily extended to the step portion 11J. Consequently, the amount of active gas adsorbed and fixed can be increased. This prevents degradation inside the joint portion. i.e. the joint layer 22, between the substrate metal layer 12 and the cap metal layer 21, so that an airtight joint of high reliability can be obtained.

[Method of Manufacturing Substrate 11 in Embodiments 1 to 4]

### (Substrate 11 in Embodiments 1 and 2)

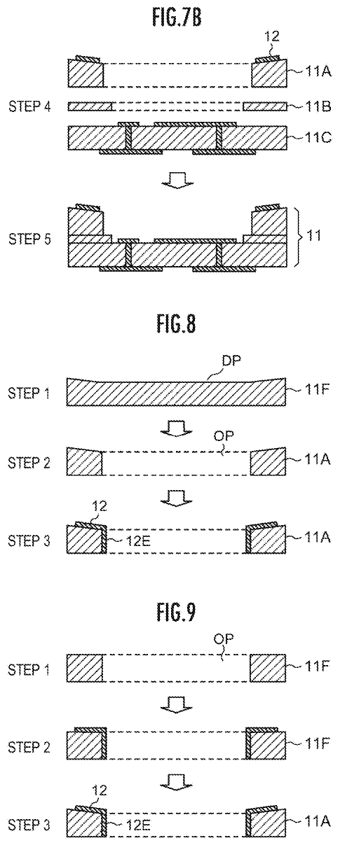

FIGS. 7A and 7B are sectional views schematically illustrating a method of manufacturing the substrate 11 in Embodiments 1 and 2.
First, a tungsten (W) pattern serving as the substrate metal layer 12 is printed on a ceramic sheet 11F serving as the frame 11A which is the frame portion (STEP 1).
Next, a recess DP is formed by press forming so as to incline the upper end surface of the frame (STEP 2).
Following this, an opening OP is formed by die cutting (STEP 3).
A ceramic sheet 11B serving as the step portion 11J is prepared by forming an opening by die cutting. Further, a substrate plate portion 11C on which the wiring electrodes 14, the mount electrodes 17, and the metal vias 18 are provided is prepared (STEP 4).
The frame 11A, the ceramic sheet 11B, and the substrate plate portion 11C are put one on top the other and brought into close contact, and burned at about 1000° C. to form the substrate 11 made of ceramic (STEP 5).

### (Substrate 11 in Embodiment 3)

FIG. 8 is a sectional view schematically illustrating a method of manufacturing the substrate 11 in Embodiment 3.
First, the recess DP is press formed in the ceramic sheet 11F serving as the frame portion (frame 11A) so as to incline the upper end surface of the frame (STEP 1).
Next, the opening OP is formed by die cutting (STEP 2).
Following this, a tungsten (W) pattern serving as the substrate metal layer 12 and the extension portion 12E is formed by spray coating (STEP 3).
The frame 11A on which the substrate metal layer 12 and the extension portion 12E have been formed, the ceramic sheet 11B, and the substrate plate portion 11C are put one on top of the other and brought into close contact, and burned at about 1000° C. to form the substrate 11 made of ceramic, in the same way as in the foregoing STEP 4 and STEP 5 (see FIG. 7B).

### (Substrate 11 in Embodiment 4)

FIG. 9 is a sectional view schematically illustrating a method of manufacturing the substrate 11 in Embodiment 4.
First, the opening OP is formed in the ceramic sheet 11F serving as the frame portion (frame 11A) by die cutting (STEP 1).
Next, a tungsten (W) pattern serving as the substrate metal layer 12 and the extension portion 12E is formed by spray coating (STEP 2).
Following this, press forming is performed so as to incline the upper end surface of the frame 11F, to form the frame 11A on which the substrate metal layer 12 and the extension portion 12E have been formed (STEP 3).
The frame 11A on which the substrate metal layer 12 and the extension portion 12E have been formed, the ceramic sheet 11B, and the substrate plate portion 11C are put one on top of the other and brought into close contact, and burned at about 1000° C. to form the substrate 11 made of ceramic, in the same way as in the foregoing STEP 4 and STEP 5 (see FIG. 7B).

The semiconductor light-emitting device according to the present invention has been described in detail above. Although the foregoing embodiments each describe a semiconductor light-emitting device including a substrate having a frame portion of a rectangular frame shape and a light-transmitting cap of rectangular plate glass, the present invention is not limited to such. For example, the frame portion of the substrate may have a polygonal frame shape, a circular frame shape, an oval frame shape, or the like, and the light-transmitting cap may have a polygonal plate shape, a circular plate shape, an oval plate shape, or the like.

As described in detail above, with the semiconductor light-emitting device and the method of manufacturing the same according to each of the foregoing embodiments, the melting start point of the joint material is set, so that the joint stability can be improved. Moreover, by setting and adjusting the volume of the joint layer between the substrate metal layer and the cap metal layer, leakage of the joint material can be prevented.

It is possible to provide a semiconductor device having an airtight joint of high reliability without residual stress which causes cracks in the joint portion, and a method of manufacturing the same.

Moreover, an airtight joint of high reliability can be obtained by preventing degradation caused by ultraviolet light and active gas inside the joint portion, i.e. the joint layer, between the substrate metal layer and the cap metal layer.

It is thus possible to provide a semiconductor device having high reliability, i.e. maintaining high airtightness even in long-term use, and having high environmental resistance such as moisture resistance and corrosion resistance, and a method of manufacturing the same.

### DESCRIPTION OF REFERENCE NUMERALS

10, 50, 60, 70 semiconductor light-emitting device
11 substrate
11A frame
11E inner wall
11J step portion
11P projecting surface
11T top surface
12 substrate metal layer
12E substrate metal layer extension portion
13 light-transmitting cap
13A window portion
13B cap joint portion
13T cap joint surface
14, 14A, 14B wiring electrode
15 semiconductor light-emitting element
21 cap metal layer
22 joint layer
22B joint material bump
22E joint layer extension portion
24 joint portion
RC recess

What is claimed is:

1. A semiconductor light-emitting device comprising:
a semiconductor light-emitting element;
a substrate having a mount portion for the semiconductor light-emitting element and a frame portion that is provided to stand on an outer peripheral part of the mount portion and has, on a top surface thereof, a substrate joint surface to which an annular substrate metal layer is fixed; and
a light-transmitting cap made of glass and having a window portion that allows light emitted from the semiconductor light-emitting element to pass through and a cap joint surface to which an annular cap metal layer of a size corresponding to the substrate metal layer is fixed, the cap joint surface being joined to the substrate metal layer by a joint layer to seal the light-transmitting cap to the substrate with an internal space that houses the semiconductor light-emitting element therein,
wherein the top surface of the frame portion is inclined to decrease in height from an outer peripheral part toward an inner peripheral part of the frame portion.

2. The semiconductor light-emitting device according to claim 1, wherein the light-transmitting cap has a plate shape.

3. The semiconductor light-emitting device according to claim 1, wherein the substrate metal layer has a metal layer extension portion extending on an inner wall of the frame portion from the top surface to cover at least part of the inner wall.

4. The semiconductor light-emitting device according to claim 3, wherein the joint layer has a joint layer extension portion extending to reach and lie on the metal layer extension portion.

5. The semiconductor light-emitting device according to claim 3, wherein the inner wall of the frame portion has a projecting surface projecting to the internal space.

6. The semiconductor light-emitting device according to claim 4, wherein the inner wall of the frame portion has a step portion formed as a step with respect to a mount surface of the mount portion and projecting to the internal space.

7. The semiconductor light-emitting device according to claim 6, wherein the joint layer extension portion at least partly reaches the step portion.

8. The semiconductor light-emitting device according to claim 1, wherein the top surface of the frame portion has a circular annular shape or a polygonal annular shape.

9. The semiconductor light-emitting device according to claim 1, wherein the joint layer is made of an AuSn joint material.

10. The semiconductor light-emitting device according to claim 4, wherein the inner wall of the frame portion has a projecting surface projecting to the internal space.

11. The semiconductor light-emitting device according to claim 5, wherein the inner wall of the frame portion has a step portion formed as a step with respect to a mount surface of the mount portion and projecting to the internal space.

12. A method of manufacturing the semiconductor light-emitting device according to claim 1, the method comprising:
depositing and arranging a plurality of joint material bumps on the cap metal layer or the substrate metal layer; and
heating the plurality of joint material bumps while pressing to cause adjacent bumps to coalesce as a result of melting, to join the cap metal layer and the substrate metal layer.

13. The method according to claim 12, wherein a joint material volume of the plurality of joint material bumps is set to prevent the joint layer from protruding out of the substrate metal layer or the cap metal layer.

14. A method of manufacturing the semiconductor light-emitting device according to claim 3, the method comprising:
depositing and arranging a plurality of joint material bumps on the cap metal layer or the substrate metal layer; and
heating the plurality of joint material bumps while pressing to cause adjacent bumps to coalesce as a result of melting, to join the cap metal layer and the substrate metal layer,
wherein a joint material volume of the plurality of joint material bumps is set to cause a melted joint material of the plurality of joint material bumps to drip onto the metal layer extension portion.
